(19) United States
(12) Patent Application Publication
(10) Pub. No.: US 2011/0168987 A1
(43) Pub. Date: Jul. 14, 2011

(54) Organic Electronic Device

(76) Inventors: Ilaria Grizzi, Cambridge (GB); Richard Wilson, Cambridge (GB); Robert Archer, Essex (GB); Matthew Roberts, Cambridge (GB)

(21) Appl. No.: 13/001,587

(22) PCT Filed: Jun. 30, 2009
(86) PCT No.: PCT/GB2009/001621

§ 371 Date: Mar. 23, 2011

(30) Foreign Application Priority Data
Jul. 1, 2008 (GB) 0812027.1

(51) Int. Cl. H01L 51/54; H01L 51/56

(52) U.S. Cl. 257/40; 438/46; 257/E51.018

(57) ABSTRACT

An organic electronic device comprising: an anode; a hole injecting layer; a cathode; and organic semiconductive material disposed between the hole injecting layer and the cathode, wherein the cathode comprises an electron-injecting material having a higher electron-injection efficiency than BaO/Al, and wherein the hole injecting layer comprises a hole injecting material which has a lower workfunction than PEDOT:PSS (1:6).

### FIELD OF THE INVENTION

The present invention relates to organic electronic devices and methods of making the same. Particular embodiments relate to organic light emissive devices.

### BACKGROUND OF THE INVENTION

Organic light emissive devices (OLEDs) generally comprise a cathode, an anode and an organic light emissive region between the cathode and the anode. Light emissive organic materials may comprise small molecular materials such as described in U.S. Pat. No. 4,539,507 or polymeric materials such as those described in PCT/WO90/13148. The cathode injects electrons into the light emissive region and the anode injects holes. The electrons and holes combine to generate photons at a recombination zone in the light-emissive region.

FIG. 1 shows a typical cross-sectional structure of an OLED. The OLED is typically fabricated on a glass or plastics substrate 1 coated with a transparent anode 2 such as an indium-tin-oxide (ITO) layer. The ITO coated substrate is covered with at least a layer of a thin film of an electroluminescent organic material 3 and cathode material 4. Other layers may be added to the device, for example to improve charge transport between the electrodes and the electroluminescent material.

In one arrangement shown in FIG. 1, the substrate 1 and the anode 2 are transparent to allow light emitted by the electroluminescent organic layer 3 to pass therethrough. Such an arrangement is known as a bottom-emitting device. In another arrangement the cathode 4 is transparent so as to allow light emitted from the electroluminescent organic layer 3 to pass therethrough. Such an arrangement is known as a top-emitting device.

There has been a growing interest in the use of OLEDs in display applications because of their potential advantages over conventional displays. OLEDs have relatively low operating voltage and power consumption and can be easily processed to produce large area displays. On a practical level, there is a need to produce OLEDs which are bright and operate efficiently but which are also reliable to produce and stable in use.

The structure of the cathode in OLEDs is one aspect under consideration in this art. In the case of a monochrome OLED, the cathode may be selected for optimal performance with a single electroluminescent organic material. However, a full colour OLED comprises red, green and blue light organic emissive materials. Such a device requires a cathode capable of injecting electrons into all three emissive materials, i.e. a “common electrode”.

Cathode 4 may be selected from materials that have a workfunction allowing injection of electrons into the electroluminescent layer. Other factors influence the selection of the cathode such as the possibility of adverse interactions between the cathode and the electroluminescent material. The cathode may consist of a single material such as a layer of aluminium. Alternatively, it may comprise a plurality of metals, for example a bilayer of calcium and aluminium as disclosed in WO 98/10621, elemental barium disclosed in WO 98/57381, Appl. Phys. Lett. 2002, 81(4), 634 and WO 02/84759 or a thin layer (1 to 15 nm) of dielectric material to assist electron injection, for example lithium fluoride disclosed in WO 00/48258 or barium fluoride, disclosed in Appl. Phys. Lett. 2001, 79(5), 2001. In order to provide efficient injection of electrons into the device, the cathode preferably has a workfunction of less than 3.5 eV, more preferably less than 3.2 eV, most preferably less than 3 eV.

A layer of metal fluoride located between the organic emissive layer (or organic electron transporting layer, if present) and the metal cathode can result in an improvement in device efficiency—see for example Appl. Phys. Lett. 70, 152, 1997. This improvement is believed to result from a reduction in the barrier height at the polymer/cathode interface, allowing improved electron injection into the organic layer(s). A mechanism of device degradation using the LiF/Al cathode is proposed in Appl. Phys. Lett. 79(5), 563-565, 2001 wherein LiF and Al may react to release Li atoms that can migrate into the electroluminescent layer and dope the electroluminescent material. However, the present inventors have found the LiF/Al cathode to be relatively stable, its main drawback being relatively low efficiency (in particular when used as a common cathode). A more efficient arrangement utilises a tri-layer of LiF/Ca/Al, which is described as a common cathode in Synth. Metals 2000, 111-112, p. 125-128. However, it is reported in WO 03/019696 that degradation is particularly marked for devices comprising this cathode and fluorescent electroluminescent materials comprising sulfur such as the red emitting polymer comprising the trimer repeat unit thiophene-benzothiadiazole-thiophene. WO 03/019696 proposes using a barium based material rather than LiF and discloses a tri-layer structure of BaF₂/Ca/Al for these fluorescent electroluminescent materials comprising sulfur. The use of other barium compounds including barium halides and barium oxide is also mentioned as a possibility in WO 03/019696. The barium compound layer is disclosed as having a thickness in the range 1 to 6 nm.

WO 03/012891 proposes using a bilayer of sodium fluoride or potassium fluoride with aluminium thereover.

U.S. Pat. No. 6,563,262 proposes using a bilayer of a metal oxide (e.g. BaO) with aluminium for fluorescent poly(p-phenylene vinylene) emissive materials (PPVs). The metal oxide layer is disclosed as having a thickness in the range 1.5 to 20 nm.

In light of the above, it can be seen that there are various disclosures of using thin metal compound layers as electron-injecting layers in a cathode of an organic light emissive device. Of the aforementioned cathode structures, the present applicant had found that prior to the present invention a device comprising a BaO electron-injecting layer had the best overall functionality taking into account factors such as opto-electrical efficiency, initial drive voltage, drive voltage stability, and lifetime. A standard device structure using such an electron-injecting layer is illustrated in FIG. 2. The device comprises: a substrate 20; an anode 22, a hole injection layer 24 comprising doped PEDOT; a hole transport layer 26 comprising, for example, a triarylamine hole transporting polymer; an organic electroluminescent layer 28; and a cathode 30 comprising a BaO electron-injecting layer 30a and a capping layer 30b of, for example, aluminium.

It is an aim of embodiments of the present invention to provide an organic light emissive device which has better overall functionality than the aforementioned device structure comprising a BaO electron-injecting layer.

### SUMMARY OF THE INVENTION

The present applicant has investigated why devices comprising a BaO electron-injecting layer perform better than devices comprising other types of electron-injecting layer. On the face of it, there is significant number of electron-injecting materials which are better electron-injectors than BaO.

By “better electron-injectors” we mean materials which have a better electron-injection efficiency (i.e. lower effective workfunction) than BaO. In practice, one way of measuring this property is to plot the current density vs drive voltage characteristics of devices whose structure differs only in the electron-injecting material used. A device which requires a lower drive voltage to attain a certain current density has better electron-injection efficiency than one which requires a higher drive voltage to attain the same current density. Thus it is possible to tabulate different electron-injecting materials in order of electron-injecting efficiency.

The present applicant has found that while devices comprising better electron-injecting materials have a lower initial drive voltage than BaO devices, the drive voltage increases relatively rapidly over time eventually becoming worse than the BaO devices. Thus, the drive voltage stability for such devices is poor and may in poor device lifetime. In addition poor voltage stability will lead to a higher power consumption (the voltage required increases as the device is being driven) and will be a hurdle fort the electronic supporting the display. As such, BaO has been preferred.

The present applicant has also found that when using a BaO electron-injection layer, changing the hole injection material from the standard doped PEDOT material to a different hole injection material has little effect on the drive-voltage characteristics of the device. By “standard doped PEDOT material” as used herein is meant PEDOT doped with poly(styrene sulfonate) in a molar ratio of 1:6, hereinafter referred to as PEDOT:PSS (1:6). This material is available from H C Starck of Leverkusen, German, as Baytron AI4083).

However, the present applicant has found that if both the electron-injecting material and the hole-injecting material are changed in combination then it is possible to achieve better device performance than the current best device structure comprising doped PEDOT:PSS (1:6) hole-injecting material and BaO electron-injecting material. In particular, the present applicant has found that if the standard doped PEDOT:PSS (1:6) hole-injection material is replaced with a material having a lower workfunction (i.e. a shallower HOMO level) and a better match with the HOMO level of the adjacent semiconductive organic material, and if the BaO electron-injection layer is replaced with a better electron-injecting material (i.e. a lower effective workfunction), then the resultant device has a lower initial drive voltage but also surprisingly now has good drive voltage stability over time. This results in a lower voltage at the end of lifetime testing (voltage when brightness has fallen by 50% at constant current, abbreviated as T50) which is ultimately the most desirable for a display application. In practice, the workfunction of the hole-injecting materials may be measured using Kelvin Probe, or ultraviolet photoelectron spectroscopy (AC-2).

Without wishing to be bound by any theory, the inventors believe that the difference between the HOMO level of the PEDOT hole injection material and the HOMO adjacent of the adjacent semiconductive organic material results in a dipole forming at the interface between these two layers which inhibits charge transfer across the interface. However, in BaO electron-injecting devices it is believed that the difference between the effective workfunction between the cathode and the semiconductive organic material causes a barrier to electron-injection which has a much larger effect on the functioning of the device. As such, in BaO devices it is electron injection which is the limiting factor on device performance and thus changing the hole-injection material has little effect on the functioning of the device.

In contrast, if a better electron-injecting material is used in place of BaO, the barrier to electron injection is reduced and hole injection becomes the limiting factor on device performance. Over time, the dipole at the interface between the hole injecting material and the semiconductive organic material increases. This effect is emphasised in a device having a good electron-injection material due to the large amount of negative charge injected into the semiconductive organic material which may increase the size of the dipole created between the hole-injecting material and the organic semiconductive material. Furthermore, it is believed that the recombination zone is also pushed towards the hole-injecting interface by an increase in the negative charge injected into the semiconductive organic material which may also contribute to a reduction in the efficiency of the device. By switching to a hole-injection material having a HOMO level which is better matched with the HOMO level of the adjacent organic semiconductive material the dipole at the interface between these layers is reduced and hole injection is thus increased. Accordingly, a better balance is achieved between electron injection and hole injection resulting in more stable device performance.

In light of the above, and in accordance with a first aspect of the present invention, there is provided an organic electronic device comprising: an anode; a hole injecting layer; a cathode; and organic semiconductive material disposed between the hole injecting layer and the cathode, wherein the cathode comprises an electron-injecting material having a higher electron-injection efficiency than BaO, and wherein the hole injecting layer comprises a hole injecting material which has a lower workfunction than PEDOT:PSS (1:6).

The combination of an electron-injecting material having a higher electron-injection efficiency than BaO and a hole injecting material which has a lower workfunction than PEDOT:PSS (1:6) has been found to result in an organic electronic device which has increased opto-electrical efficiency, a lower initial drive voltage and good drive voltage stability when compared with previous arrangements which results in lower voltage at the end of T50.

Suitable hole injecting materials are available from Plextronics Inc. Some examples are described in WO 2006/036755. This document describes hole injecting material comprising region-regular poly(3-substitutedthiophene). However, it will be clear from the aforementioned discussion that the advantageous features of the present invention are not limited to these particular materials and that any material having a lower workfunction than PEDOT may be used.

Suitable electron-injecting materials include fluorides and in particular alkali fluorides such as NaF and KF. Other examples include carbonates such as CsCO₃. However, it will be clear from the aforementioned discussion that the advantageous features of the present invention are not limited to these particular materials and that any material having a higher electron-injection efficiency than BaO may be used.

The difference between the workfunction of the hole injecting material and the HOMO level of the organic semiconductive material adjacent the hole injecting layer is preferably 0.2 eV or less, more preferably 0.1 eV or less. More preferably still, there is substantially no energy difference between the workfunction of the hole injecting material and the HOMO level of the organic semiconductive material adjacent the hole injecting layer. This will minimize or eliminate any dipole moment forming at the interface between the hole injecting material and the organic semiconductive material during use of the device.

According to one embodiment the organic semiconductive material comprises a layer of semiconductive light-emissive material thus forming a light emissive device. A single layer of such material may be provided between the hole injecting layer and the cathode. However, more preferably a layer of semiconductive hole transporting material is provided between the hole injecting layer and the light-emissive layer.

According to another aspect of the present invention there is provided a method of manufacturing an organic electronic device according to any preceding claim comprising: depositing a hole injecting layer over an anode; depositing organic semiconductive material over the hole injecting layer; and depositing a cathode over the organic semiconductive material, wherein the cathode comprises an electron-injecting material having a higher electron-injection efficiency than BaO, and wherein the hole injecting layer comprises a hole injecting material which has a lower workfunction than PEDOT:PSS (1:6).

According to certain embodiments, one or more of the hole injecting layer, the hole transporting layer, and the light-emissive layer are deposited from solution.

Preferably, the electron injecting layer has a thickness of up to 10 nm, more preferably up to 5 nm.

The cathode preferably comprises a capping layer disposed over the electron injecting material. The capping layer may comprise a metal having a workfunction greater than 3.7 eV, more preferably greater than 3.9 eV. Examples of suitable materials are Al, Ag and NiCr.

An encapsulation coating comprising one or more polymer layers and/or one or more dielectric layers may be deposited over the cathode. Preferably, the encapsulation coating comprises alternating polymer and dielectric layers. Alternatively, the device may be encapsulated using an enclosure such as a glass or metal “can” that is applied over the device and adhered to the substrate in order to enclose the device.

### BRIEF DESCRIPTION OF THE DRAWINGS

The present invention will now be described in further detail, by way of example only, with reference to the accompanying drawings in which:

FIG. 1 shows in diagrammatic form a typical cross-sectional structure of an OLED;

FIG. 2 shows another known OLED structure;

FIG. 3 shows an OLED according to an embodiment of the present invention;

FIG. 4 shows a graph of current density vs voltage for two different devices illustrating how to measure relative electron-injection efficiency for different electron-injecting materials;

FIG. 5 shows a graph of voltage vs time for four different devices, three of which are not according to the presently claimed invention and one of which is an embodiment of the present invention; and

FIGS. 6(a) to 6(d) illustrate the energy levels for the four different devices of FIG. 5.

### DETAILED DESCRIPTION OF PREFERRED EMBODIMENTS

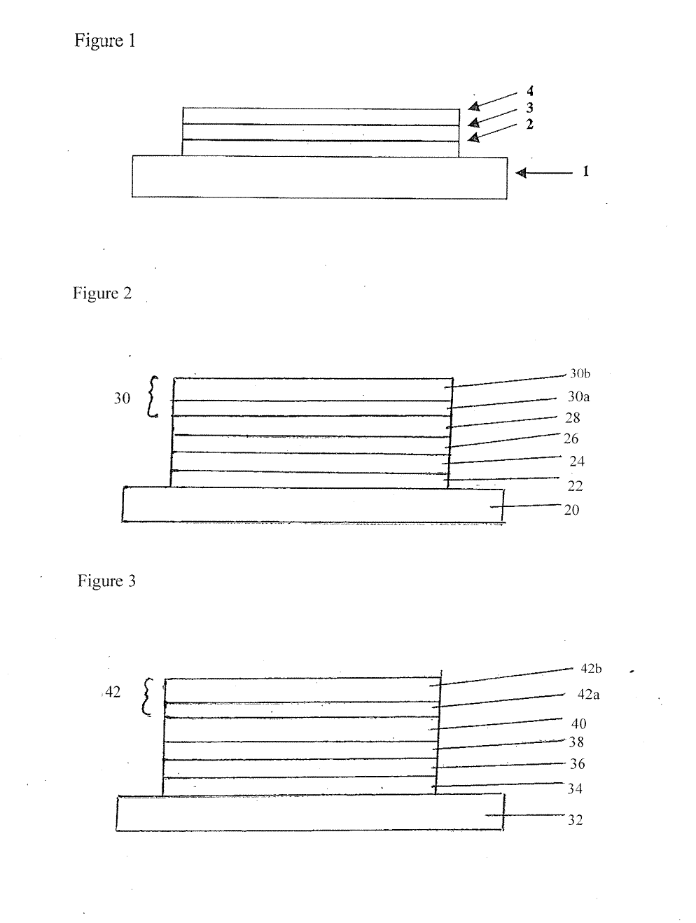

FIGS. 1 and 2 have been previously described and show in diagrammatic form typical cross-sectional structures of known OLEDs. FIG. 3 shows a cross-sectional structure of an OLED according to an embodiment of the present invention. The structure is similar to that illustrated in FIG. 2 but differs in the materials used for the hole-injecting and electron-injecting layers.

The device of FIG. 3 comprises: a substrate 32; an anode 34, a hole injection layer 36 comprising a hole injecting material which has a lower workfunction than PEDOT:PSS (1:6); a hole transport layer 38 comprising, for example, a triarylamine hole transporting polymer; an organic electroluminescent layer 40; and a cathode 42 comprising an electron-injecting layer 42a comprising an electron-injecting material having a higher electron-injection efficiency than BaO and a capping layer 42b of, for example, aluminium.

To illustrate the advantageous features of the present invention a comparison of five different devices is set out below. The four devices all have a similar layer structure to that illustrated in FIGS. 2 and 3 and are identical in terms of the anode, hole injecting layer and organic electroluminescent layer. The devices only differ in respect of the hole-injecting and electron-injecting materials used in the devices as follows:

Device 1 comprises a BaO/Al bilayer cathode and a PEDOT:PSS (1:6) hole injecting layer (HIL1);

Device 2 comprises a BaO/Al bilayer cathode and a Plextronics Inc. hole injecting layer (HIL2) with a lower workfunction than PEDOT:PSS (1:6);

Device 3 comprises an NaF/Al bilayer cathode and a PEDOT:PSS (1:6) hole injecting layer (HIL1); and

Device 4 comprises an NaF/Al bilayer cathode and a Plextronics Inc. hole injecting layer (HIL2) with a lower workfunction than PEDOT:PSS (1:6).

Device 5 comprises an NaF/Al bilayer cathode and a PEDOT:PSS (1:2.5) hole injecting layer with a lower workfunction than PEDOT:PSS (1:6).

Of these five devices only Devices 4 and 5 are an embodiment of the present invention.

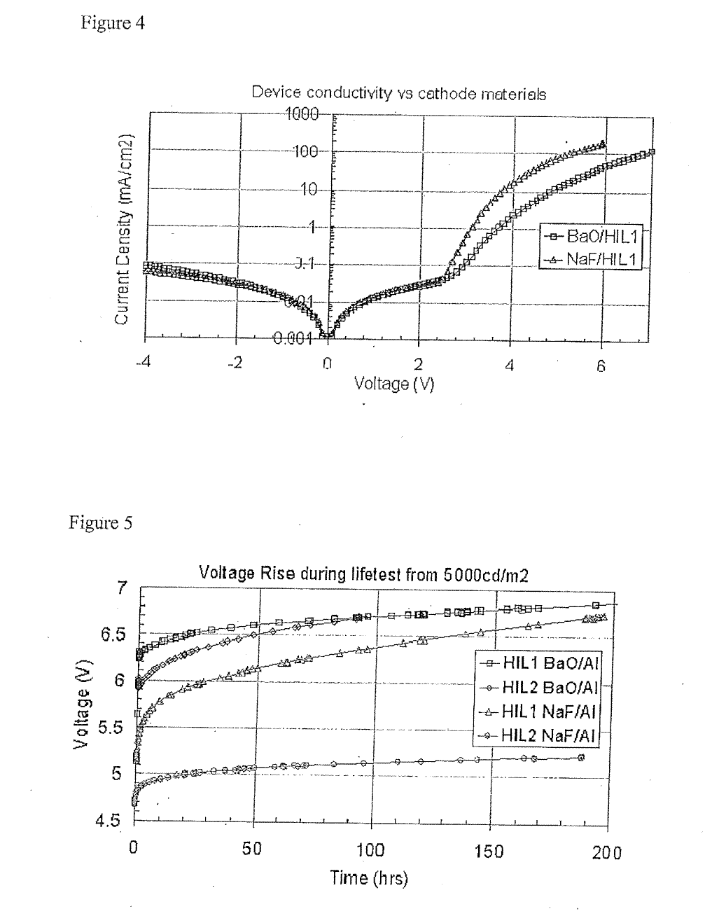

FIG. 4 shows a graph of current density vs voltage for devices 1 and 3. The only difference between these devices is that Device 1 uses a BaO/Al cathode whereas Device 3 uses an NaF/Al cathode. Device conductivity is clearly higher for the NaF/Al cathode. For example, the drive voltage required to attain 10 mA/cm² is reduced from ˜4.8V for BaO/Al to ˜3.8V for NaF/Al. This shows that electron injection efficiency for NaF is better than for BaO.

FIG. 5 shows a graph of voltage vs time for the four different devices. The top line is for Device 1, the second line down is for Device 2, the third line down is for Device 3, and the bottom line in the graph is for Device 4.

It can be seen that the voltage vs time characteristics for the BaO/Al bilayer cathode devices (Devices 1 and 2—the two top lines in the graph) are similar despite the fact that they comprise different hole-injecting materials. Device 3, which uses an NaF/Al cathode, has a lower initial voltage but this rises rapidly during operation of the device and eventually will rise above the BaO/Al devices. In contrast, Device 4, which uses a combination of the NaF/Al cathode and the Plextronics Inc. hole injecting layer, has a lower initial voltage which remains low during operation of the device. As such, it can be seen that Device 4 shows the best characteristics with lowest voltage at T50.

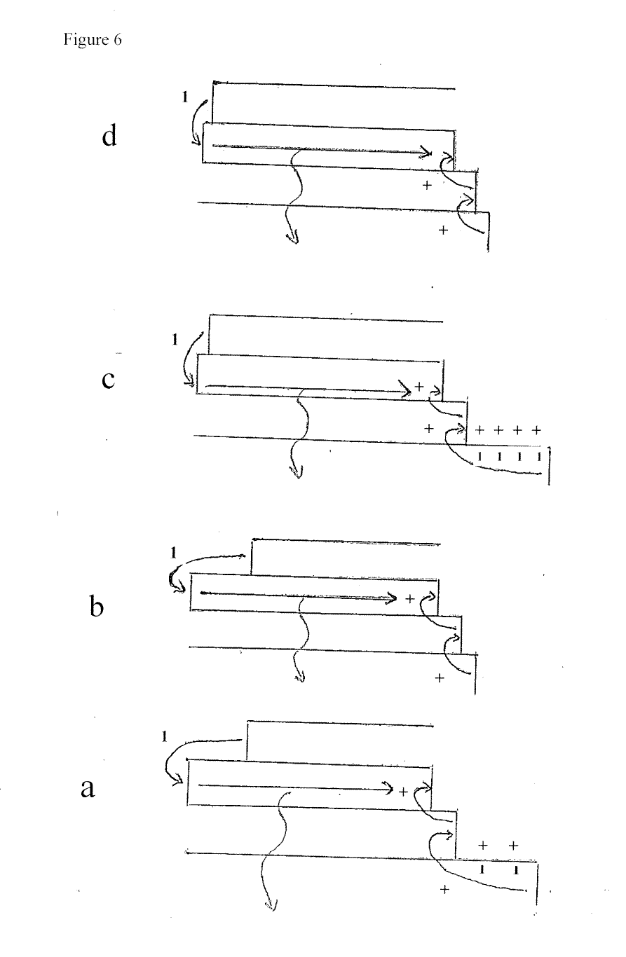

FIGS. 6(a) to 6(d) illustrate the energy levels for devices 1 to 4 respectively. Four layers are shown for each device (moving from left to right): the hole-injecting layer; the hole-transporting layer; the organic electroluminescent layer; and the electron-injecting layer. In the Figures, holes are injected from the left while electrons are injected from the right. These combine in the organic electroluminescent layer to emit light as indicated by the wavy arrow.

FIG. 6(a) illustrates the situation for Device 1 which comprises a BaO/Al bilayer cathode and a PEDOT:PSS (1:6) hole injecting layer. There is a significant difference in energy between the HOMO level of the PEDOT:PSS (1:6) hole-injecting material and the HOMO of the hole-transporting material. This results in a dipole forming at the interface between the two layers. However, device operation is dominated by the barrier to electron injection at the interface between the BaO electron-injecting layer and the organic electroluminescent layer as the LUMO of the organic electroluminescent material is significantly higher than the energy of the electrons in the BaO/Al cathode structure. This can be seen by comparison with FIG. 6(b) which illustrates to situation for Device 2. Here, the hole-injecting material has been changed to the Plextronics Inc. hole injecting material which has a HOMO which is higher than that of the PEDOT:PSS (1:6) of Device 1 (i.e. the Plextronics Inc. hole injecting material has a lower workfunction than the PEDOT:PSS (1:6) of Device 1). Thus, the HOMO level of the hole-injecting material is more closely matched to that of the hole-transporting material. Despite this, it can be seen that the voltage vs time characteristics remain similar to those of Device 1. This indicates that electron injection rather than hole injection is the dominant factor for BaO/Al cathode devices.

FIG. 6(c) illustrates the situation for Device 3 which comprises an NaF/Al bilayer cathode and a PEDOT:PSS (1:6) hole injecting layer. The barrier to electron injection between the electron-injecting layer and the organic electroluminescent layer is much reduced due to the lower effective workfunction of the NaF/Al cathode (higher energy level for electron injection). That is, the NaF has a higher electron injection efficiency when compared with the BaO. As a result, the initial drive voltage of the device is lower than the BaO/Al devices 1 and 2. However, the drive voltage increases rapidly during operation and continues to rise during use. Without wishing to be bound by any theory, this may be attributed to a large dipole developing at the interface between the hole-injecting layer and the hole-transporting layer and/or a movement of the recombination zone (towards the left in the Figure) which may result in the recombination zone moving at least partially into the hole-transporting layer.

FIG. 6(d) illustrates the situation for Device 4 which comprises an NaF/Al bilayer cathode and the Plextronics Inc. hole injecting material which has a HOMO which is higher than that of PEDOT:PSS (1:6). Thus, the HOMO level of the hole-injecting material is more closely matched to that of the hole-transporting material. Furthermore, the barrier to electron injection between the electron-injecting layer and the organic electroluminescent layer is much reduced due to the lower effective workfunction of the NaF/Al cathode (higher energy level for electron injection). It is thought that this combination of features provides a better balance between hole injection and electron injection during the operation of the device when compared to Device 3 resulting in a low and stable drive voltage during operation as shown in FIG. 5.

A further device, Device 5, was prepared as per Device 1 except that PEDOT:PSS (1:6) was replaced with PEDOT:PSS having a molar ratio of 1:2.5, which has a lower workfunction than PEDOT:PSS (1:6). Device 5 was found to have a drive voltage 0.4 V lower than Device 1. Again, this is attributed to the lower workfunction of the hole injection layer used in Device 5.

While the present invention has been illustrated above with reference to a device comprising an NaF/Al bilayer cathode and a Plextronics Inc. hole injecting material, it is clear than the principles of the invention may be applied to any electron-injecting material having a higher electron-injection efficiency than BaO in combination with any hole injecting material which has a lower workfunction than PEDOT:PSS (1:6).

Other features of embodiments of the present invention are described below.

### Charge Transport Layers

If present, a hole transporting layer preferably has a HOMO level of higher than or equal to −5.2 eV, more preferably around −4.8-5.0 eV. HOMO levels may be measured by cyclic voltammetry, for example.

If present, an electron transporting layer located between electroluminescent layer 3 and cathode 4 preferably has a LUMO level of around 3-3.5 eV.

### Electroluminescent Layer

The electroluminescent layer may consist of the electroluminescent material alone or may comprise the electroluminescent material in combination with one or more further materials. In particular, the electroluminescent material may be blended with hole and/or electron transporting materials as disclosed in, for example, WO 99/48160, or may comprise a luminescent dopant in a semiconducting host matrix. Alternatively, the electroluminescent material may be covalently bound to a charge transporting material and/or host material.

The electroluminescent layer may be patterned or unpatterned. A device comprising an unpatterned layer may be used an illumination source, for example. A white light emitting device is particularly suitable for this purpose. A device comprising a patterned layer may be, for example, an active matrix display or a passive matrix display. In the case of an active matrix display, a patterned electroluminescent layer is typically used in combination with a patterned anode layer and an unpatterned cathode. In the case of a passive matrix display, the anode layer is formed of parallel stripes of anode material, and parallel stripes of electroluminescent material and cathode material arranged perpendicular to the anode material wherein the stripes of electroluminescent material and cathode material are typically separated by stripes of insulating material (“cathode separators”) formed by photolithography.

Suitable materials for use in electroluminescent layer include small molecule, polymeric and dendrimeric materials, and compositions thereof. Suitable electroluminescent polymers include poly(arylene vinylenes) such as poly(p-phenylene vinylenes) and polyarylenes such as: polyfluorenes, particularly 2,7-linked 9,9 dialkyl polyfluorenes or 2,7-linked 9,9 diaryl polyfluorenes; polyspirofluorenes, particularly 2,7-linked poly-9,9-spirofluorene; polyindenofluorenes, particularly 2,7-linked polyindenofluorenes; polyphenylenes, particularly alkyl or alkoxy substituted poly-1,4-phenylene. Such polymers as disclosed in, for example, Adv. Mater, 2000 12(23) 1737-1750 and references therein. Suitable electroluminescent dendrimers include electroluminescent metal complexes bearing dendrimeric groups as disclosed in, for example, WO 02/066552.

### Cathode

The cathode may be opaque or transparent. Transparent cathodes are particularly advantageous for active matrix devices because emission through a transparent anode in such devices is at least partially blocked by drive circuitry located underneath the emissive pixels.

### Encapsulation

Optical devices tend to be sensitive to moisture and oxygen. Accordingly, the substrate preferably has good barrier properties for prevention of ingress of moisture and oxygen into the device. The substrate is commonly glass, however alternative substrates may be used, in particular where flexibility of the device is desirable. For example, the substrate may comprise a plastic as in U.S. Pat. No. 6,268,695 which discloses a substrate of alternating plastic and barrier layers or a laminate of thin glass and plastic as disclosed in EP 0949850.

The device is preferably encapsulated with an encapsulant to prevent ingress of moisture and oxygen. Suitable encapsulants include a sheet of glass, films having suitable barrier properties such as alternating stacks of polymer and dielectric as disclosed in, for example, WO 01/81649 or an airtight container as disclosed in, for example, WO 01/19142. A getter material for absorption of any atmospheric moisture and/or oxygen that may permeate through the substrate or encapsulant may be disposed between the substrate and the encapsulant.

Conjugated Polymers (Fluorescent and/or Charge Transporting)

Suitable electroluminescent and/or charge transporting polymers include poly(arylene vinylenes) such as poly(p-phenylene vinylenes) and polyarylenes.

Polymers preferably comprise a first repeat unit selected from arylene repeat units as disclosed in, for example, Adv. Mater. 2000 12(23) 1737-1750 and references therein. Exemplary first repeat units include: 1,4-phenylene repeat units as disclosed in J. Appl. Phys. 1996, 79, 934; fluorene repeat units as disclosed in EP 0842208; indenofluorene repeat units as disclosed in, for example, Macromolecules 2000, 33(6), 2016-2020; and spirofluorene repeat units as disclosed in, for example EP 0707020. Each of these repeat units is optionally substituted. Examples of substituents include solubilising groups such as C₁₋₂₀ alkyl or alkoxy; electron withdrawing groups such as fluorine, nitro or cyano; and substituents for increasing glass transition temperature (Tg) of the polymer.

Particularly preferred polymers comprise optionally substituted, 2,7-linked fluorenes, most preferably repeat units of formula I:

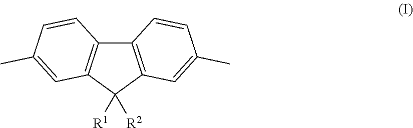

wherein R¹ and R² are independently selected from hydrogen or optionally substituted alkyl, alkoxy, aryl, arylalkyl, heteroaryl and heteroarylalkyl. More preferably, at least one of R¹ and R² comprises an optionally substituted C₄-C₂₀ alkyl or aryl group.

Polymers may provide one or more of the functions of hole transport, electron transport and emission depending on which layer of the device it is used in and the nature of co-repeat units. In particular:
a homopolymer of fluorene repeat units, such as a homopolymer of 9,9-dialkylfluoren-2,7-diyl, may be utilised to provide electron transport.
a copolymer comprising triarylamine repeat unit, in particular a repeat unit II:

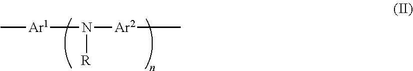

wherein Ar¹ and Ar² are optionally substituted aryl or heteroaryl groups, n is greater than or equal to 1, preferably 1 or 2, and R is H or a substituent, preferably a substituent. R is preferably alkyl or aryl or heteroaryl, most preferably aryl or heteroaryl. Any of the aryl or heteroaryl groups in the unit of formula 1 may be substituted. Preferred substituents include alkyl and alkoxy groups. Any of the aryl or heteroaryl groups in the repeat unit of Formula 1 may be be linked by a direct bond or a divalent linking atom or group. Preferred divalent linking atoms and groups include O, S; substituted N; and substituted C.

Particularly preferred units satisfying Formula II include units of Formulae 2 to 4:

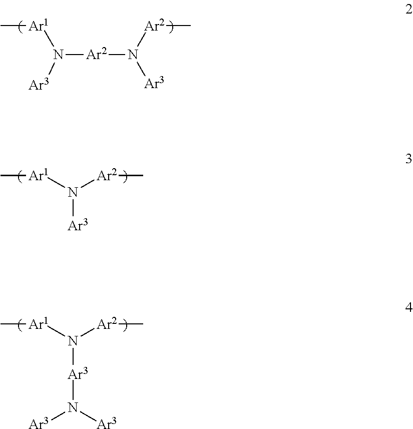

wherein Ar¹ and Ar² are as defined above; and Ar³ is optionally substituted aryl or heteroaryl. Where present, preferred substituents for Ar³ include alkyl and alkoxy groups.

Particularly preferred hole transporting polymers of this type are copolymers of the first repeat unit and a triarylamine repeat unit.

a copolymer comprising a first repeat unit and heteroarylene repeat unit may be utilised for charge transport or emission. Preferred heteroarylene repeat units are selected from formulae 7-21:

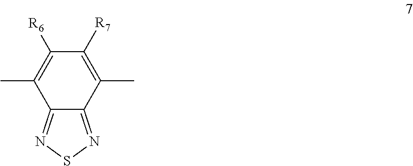

wherein R₆ and R₇ are the same or different and are each independently hydrogen or a substituent group, preferably alkyl, aryl, perfluoroalkyl, thioalkyl, cyano, alkoxy, heteroaryl, alkylaryl or arylalkyl. For ease of manufacture, R₆ and R₇ are preferably the same. More preferably, they are the same and are each a phenyl group.

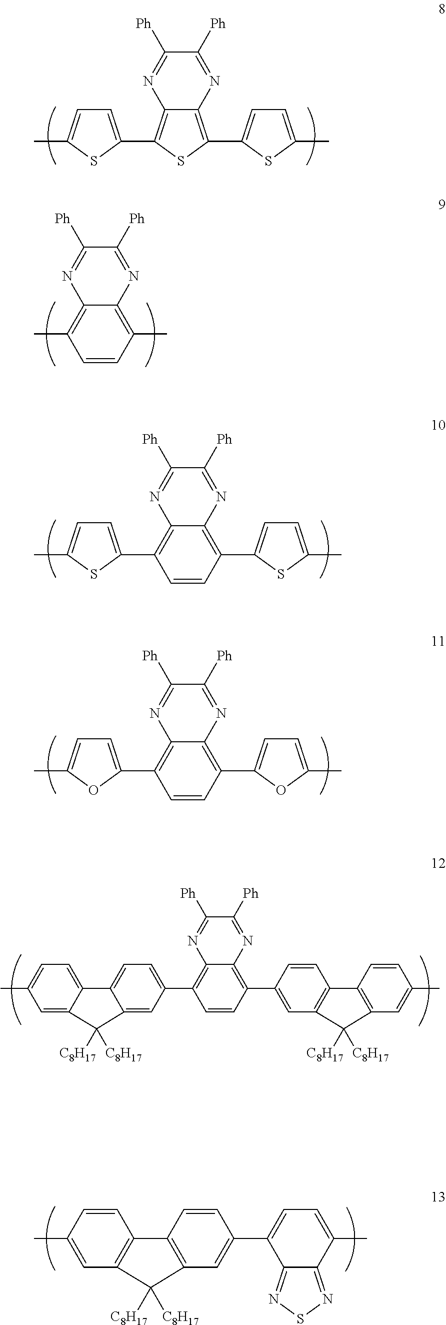

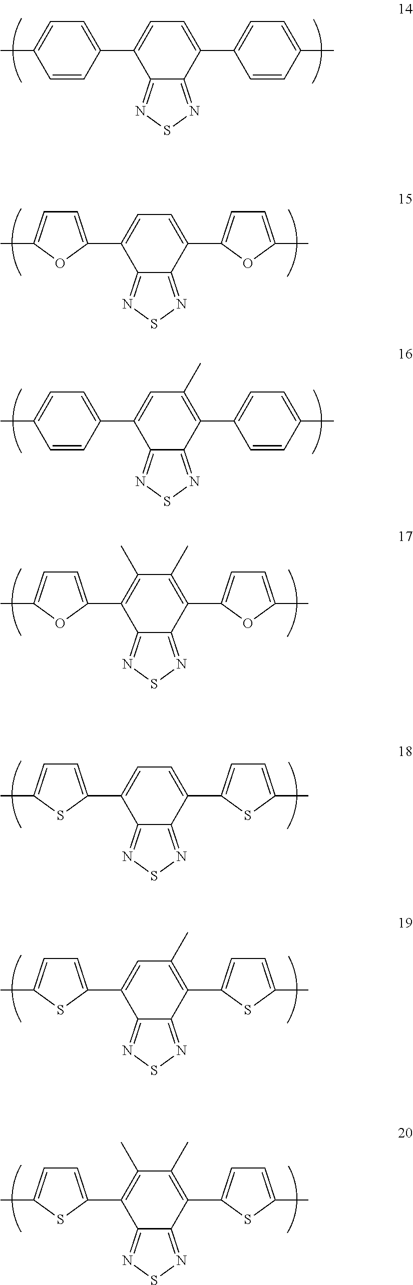

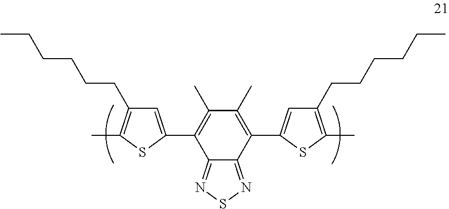

Electroluminescent copolymers may comprise an electroluminescent region and at least one of a hole transporting region and an electron transporting region as disclosed in, for example, WO 00/55927 and U.S. Pat. No. 6,353,083. If only one of a hole transporting region and electron transporting region is provided then the electroluminescent region may also provide the other of hole transport and electron transport functionality. Alternatively, an electroluminescent polymer may be blended with a hole transporting material and/or an electron transporting material. Polymers comprising one or more of a hole transporting repeat unit, electron transporting repeat unit and emissive repeat unit may provide said units in a polymer main-chain or polymer side-chain.

The different regions within such a polymer may be provided along the polymer backbone, as per U.S. Pat. No. 6,353,083, or as groups pendant from the polymer backbone as per WO 01/62869.

### Polymerisation Methods

Preferred methods for preparation of these polymers are Suzuki polymerisation as described in, for example, WO 00/53656 and Yamamoto polymerisation as described in, for example, T. Yamamoto, “Electrically Conducting And Thermally Stable π—Conjugated Poly(arylene)s Prepared by Organometallic Processes”, Progress in Polymer Science 1993, 17, 1153-1205. These polymerisation techniques both operate via a “metal insertion” wherein the metal atom of a metal complex catalyst is inserted between an aryl group and a leaving group of a monomer. In the case of Yamamoto polymerisation, a nickel complex catalyst is used; in the case of Suzuki polymerisation, a palladium complex catalyst is used.

For example, in the synthesis of a linear polymer by Yamamoto polymerisation, a monomer having two reactive halogen groups is used. Similarly, according to the method of Suzuki polymerisation, at least one reactive group is a boron derivative group such as a boronic acid or boronic ester and the other reactive group is a halogen. Preferred halogens are chlorine, bromine and iodine, most preferably bromine.

It will therefore be appreciated that repeat units and end groups comprising aryl groups as illustrated throughout this application may be derived from a monomer carrying a suitable leaving group.

Suzuki polymerisation may be used to prepare regioregular, block and random copolymers. In particular, homopolymers or random copolymers may be prepared when one reactive group is a halogen and the other reactive group is a boron derivative group. Alternatively, block or regioregular, in particular AB, copolymers may be prepared when both reactive groups of a first monomer are boron and both reactive groups of a second monomer are halogen.

As alternatives to halides, other leaving groups capable of participating in metal insertion include groups include tosylate, mesylate and triflate.

### Solution Processing

A single polymer or a plurality of polymers may be deposited from solution to form the electroluminescent layer. Suitable solvents for polyarylenes, in particular polyfluorenes, include mono- or poly-alkylbenzenes such as toluene and xylene. Particularly preferred solution deposition techniques are spin-coating and inkjet printing.

Spin-coating is particularly suitable for devices wherein patterning of the electroluminescent material is unnecessary—for example for lighting applications or simple monochrome segmented displays.

Inkjet printing is particularly suitable for high information content displays, in particular full colour displays. Inkjet printing of OLEDs is described in, for example, EP 0880303.

Other solution deposition techniques include dip-coating, roll printing and screen printing.

If multiple layers of the device are formed by solution processing then the skilled person will be aware of techniques to prevent intermixing of adjacent layers, for example by crosslinking of one layer before deposition of a subsequent layer or selection of materials for adjacent layers such that the material from which the first of these layers is formed is not soluble in the solvent used to deposit the second layer.

### Hosts for Phosphorescent Emitters

Numerous hosts are described in the prior art including “small molecule” hosts such as 4,4′-bis(carbazol-9-yl)biphenyl), known as CBP, and (4,4′,4″-tris(carbazol-9-yl)triphenylamine), known as TCTA, disclosed in lkai et al., Appl. Phys. Lett., 79 no. 2, 2001, 156; and triarylamines such as tris-4-(N-3-methylphenyl-N-phenyl)phenylamine, known as MTDATA. Polymers are also known as hosts, in particular homopolymers such as poly(vinyl carbazole) disclosed in, for example, Appl. Phys. Lett. 2000, 77(15), 2280; polyfluorenes in Synth. Met. 2001, 116, 379, Phys. Rev. B 2001, 63, 235206 and Appl. Phys. Lett. 2003, 82(7), 1006; poly[4-(N-4-vinylbenzyloxyethyl, N-methylamino)-N-(2,5-di-tert-butylphenylnapthalimide] in Adv. Mater. 1999, 11(4), 285; and poly(para-phenylenes) in J. Mater. Chem. 2003, 13, 50-55. Copolymers are also known as hosts.

### Metal Complexes (Mostly Phosphorescent but Includes Fluorescent at the End)

Preferred metal complexes comprise optionally substituted complexes of formula (V):

ML¹_{q}L²ᵣL³ₛ (V)

wherein M is a metal; each of L¹, L² and L³ is a coordinating group; q is an integer; r and s are each independently 0 or an integer; and the sum of (a. q)+(b. r)+(c.s) is equal to the number of coordination sites available on M, wherein a is the number of coordination sites on L¹, b is the number of coordination sites on L² and c is the number of coordination sites on L³.

Heavy elements M induce strong spin-orbit coupling to allow rapid intersystem crossing and emission from triplet or higher states (phosphorescence). Suitable heavy metals M include:

lanthanide metals such as cerium, samarium, europium, terbium, dysprosium, thulium, erbium and neodymium; and

d-block metals, in particular those in rows 2 and 3 i.e. elements 39 to 48 and 72 to 80, in particular ruthenium, rhodium, pallaidum, rhenium, osmium, iridium, platinum and gold.

Suitable coordinating groups for the f-block metals include oxygen or nitrogen donor systems such as carboxylic acids, 1,3-diketonates, hydroxy carboxylic acids, Schiff bases including acyl phenols and iminoacyl groups. As is known, luminescent lanthanide metal complexes require sensitizing group(s) which have the triplet excited energy level higher than the first excited state of the metal ion. Emission is from an f-f transition of the metal and so the emission colour is determined by the choice of the metal. The sharp emission is generally narrow, resulting in a pure colour emission useful for display applications.

The d-block metals are particularly suitable for emission from triplet excited states. These metals form organometallic complexes with carbon or nitrogen donors such as porphyrin or bidentate ligands of formula (VI):

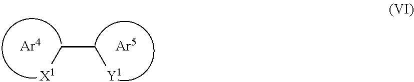

wherein Ar⁴ and Ar⁵ may be the same or different and are independently selected from optionally substituted aryl or heteroaryl; X¹ and Y¹ may be the same or different and are independently selected from carbon or nitrogen; and Ar⁴ and Ar⁵ may be fused together. Ligands wherein X¹ is carbon and Y¹ is nitrogen are particularly preferred.

Examples of bidentate ligands are illustrated below:

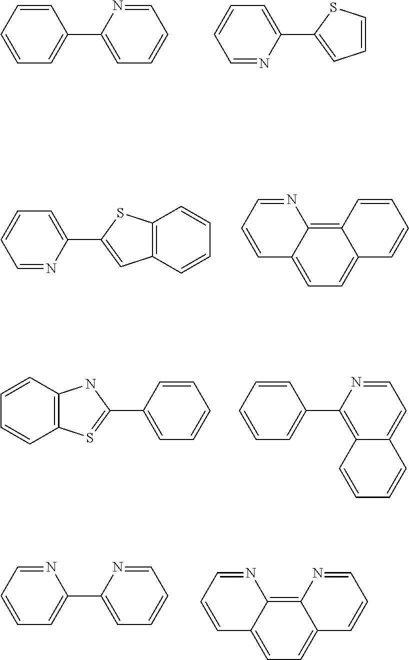

Each of Ar⁴ and Ar⁵ may carry one or more substituents. Two or more of these substituents may be linked to form a ring, for example an aromatic ring. Particularly preferred substituents include fluorine or trifluoromethyl which may be used to blue-shift the emission of the complex as disclosed in WO 02/45466, WO 02/44189, US 2002-117662 and US 2002-182441; alkyl or alkoxy groups as disclosed in JP 2002-324679; carbazole which may be used to assist hole transport to the complex when used as an emissive material as disclosed in WO 02/81448; bromine, chlorine or iodine which can serve to functionalise the ligand for attachment of further groups as disclosed in WO 02/68435 and EP 1245659; and dendrons which may be used to obtain or enhance solution processability of the metal complex as disclosed in WO 02/66552.

A light-emitting dendrimer typically comprises a light-emitting core bound to one or more dendrons, wherein each dendron comprises a branching point and two or more dendritic branches. Preferably, the dendron is at least partially conjugated, and at least one of the core and dendritic branches comprises an aryl or heteroaryl group. Other ligands suitable for use with d-block elements include diketonates, in particular acetylacetonate (acac); triarylphosphines and pyridine, each of which may be substituted.

Main group metal complexes show ligand based, or charge transfer emission. For these complexes, the emission colour is determined by the choice of ligand as well as the metal.

The host material and metal complex may be combined in the form of a physical blend. Alternatively, the metal complex may be chemically bound to the host material. In the case of a polymeric host, the metal complex may be chemically bound as a substituent attached to the polymer backbone, incorporated as a repeat unit in the polymer backbone or provided as an end-group of the polymer as disclosed in, for example, EP 1245659, WO 02/31896, WO 03/18653 and WO 03/22908.

A wide range of fluorescent low molecular weight metal complexes are known and have been demonstrated in organic light emitting devices [see, e.g., Macromol. Sym. 125 (1997) 1-48, U.S. Pat. No. 5,150,006, U.S. Pat. No. 6,083,634 and U.S. Pat. No. 5,432,014]. Suitable ligands for di or trivalent metals include: oxinoids, e.g. with oxygen-nitrogen or oxygen-oxygen donating atoms, generally a ring nitrogen atom with a substituent oxygen atom, or a substituent nitrogen atom or oxygen atom with a substituent oxygen atom such as 8-hydroxyquinolate and hydroxyquinoxalinol-10-hydroxybenzo (h) quinolinato (II), benzazoles (III), schiff bases, azoindoles, chromone derivatives, 3-hydroxyflavone, and carboxylic acids such as salicylato amino carboxylates and ester carboxylates. Optional substituents include halogen, alkyl, alkoxy, haloalkyl, cyano, amino, amido, sulfonyl, carbonyl, aryl or heteroaryl on the (hetero) aromatic rings which may modify the emission colour.

While this invention has been particularly shown and described with reference to preferred embodiments thereof, it will be understood by those skilled in the art that various changes in form and details may be made therein without departing from the scope of the invention as defined by the appended claims.

1. An organic electronic device comprising: an anode; a hole injecting layer; a cathode; and organic semiconductive material disposed between the hole injecting layer and the cathode, wherein the cathode comprises an electron-injecting material having a higher electron-injection efficiency than BaO, and wherein the hole injecting layer comprises a hole injecting material that has a lower workfunction than poly(3,4-ethylenedioxythiophene) (PEDOT) doped with poly(styrene sulfonate) in a molar ratio of 1:6.

2. An organic electronic device according to claim 1, wherein the hole injecting material comprising region-regular poly(3-substitutedthiophene).

3. An organic electronic device according to claim 1, wherein the electron-injecting material comprises at least one of a fluoride and a carbonate.

4. An organic electronic device according to claim 3, wherein the electron-injecting material is an alkali fluoride.

5. An organic electronic device according to claim 1, wherein the electron injecting material is NaF.

6. An organic electronic device according to claim 1, wherein the electron injecting material is KF.

7. An organic electronic device according to claim 1, wherein the electron injecting material is CsCO₃.

8. An organic electronic device according to claim 1, wherein the difference between the workfunction of the hole injecting material and the highest occupied molecular orbital (HOMO) level of the organic semiconductive material adjacent the hole injecting layer is 0.2 eV or less.

9. An organic electronic device according to claim 8, wherein the difference between the workfunction of the hole injecting material and the HOMO level of the organic semiconductive material adjacent the hole injecting layer is 0.1 eV or less.

10. An organic electronic device according to claim 1, wherein the organic semiconductive material comprises a layer of semiconductive light-emissive material.

11. An organic electronic device according to claim 10, wherein the organic semiconductive material comprises a layer of semiconductive hole transporting material disposed between the hole injecting layer and the light-emissive layer.

12. A method of manufacturing an organic electronic device according to claim 1 comprising:
depositing a hole injecting layer over an anode;
depositing organic semiconductive material over the hole injecting layer; and
depositing a cathode over the organic semiconductive material, wherein the cathode comprises an electron-injecting material having a higher electron-injection efficiency than BaO, and wherein the hole injecting layer comprises a hole injecting material which has a lower workfunction than poly(3,4-ethylenedioxythiophene) (PEDOT) doped with poly(styrene sulfonate) in a molar ratio of 1:6.

13. A method according to claim 12, comprising depositing one or more of the hole injecting layer, the hole transporting layer, and the light-emissive layer from solution.
